(19) United States
(12) Patent Application Publication
(10) Pub. No.: US 2022/0366329 A1
(43) Pub. Date: Nov. 17, 2022

(54) MODELING DEVICE OF BUSINESS LOGIC REPRESENTATION MODEL AND MODELING METHOD THEREOF

(71) Applicants: DATA SYSTEMS CONSULTING CO., LTD., New Taipei City (TW); Digiwin Software Co., Ltd, Shanghai (CN)

(72) Inventors: Xiaoliang Ma, Shanghai (CN); GUOXIN SUN, Shanghai (CN)

(73) Assignees: DATA SYSTEMS CONSULTING CO., LTD., New Taipei City (TW); Digiwin Software Co., Ltd, Shanghai (CN)

(21) Appl. No.: 17/372,544

(22) Filed: Jul. 12, 2021

(30) Foreign Application Priority Data
May 11, 2021 (CN) 202110510527.9

(51) Int. Cl. G06Q 10/06; G06K 9/62

(52) U.S. Cl. CPC G06Q 10/067; G06K 9/6232; G06K 9/6296

(57) ABSTRACT

A modeling device of a business logic representation model and a modeling method of the business logic representation model are provided. The modeling device of the business logic representation model includes a memory device and a processing device. The memory device is configured to store a plurality of units. The processing device is coupled to the memory device. The processing device executes the units to establish a plurality of action models and a plurality of data models according to a plurality of action metadata and establish an action logic graph according to the action models and the data models.

### CROSS-REFERENCE TO RELATED APPLICATION

This application claims the priority benefits of China application serial no. 202110510527.9, filed on May 11, 2021. The entirety of the above-mentioned patent application is hereby incorporated by reference herein and made a part of this specification.

### BACKGROUND

### Technical Field

The disclosure relates to a modeling device and a modeling method, and in particular, relates to a modeling device of a business logic representation model and a modeling method thereof.

### Description of Related Art

At present, various forms of data and business logic are available in the field of enterprise management, and information systems are used by most of the enterprises to help personnel of various functions complete daily business behaviors. Nevertheless, these business logic and data are scattered in various information systems, paper or electronic forms, and the minds and hands of employees of various functions at present. That is, conventional business logic means that most of the current systems are passively operated by users or are used to assist manual data processing rather than being used to replacing people. In other words, the conventional business logic indicates that actually, a large amount of operations are still initiated and completed manually. In this regard, the problem is that the complete business process may be complicated, and execution of the process may thus rely on people's knowledge and experience, so it is difficult to completely solidify the process into the system. Alternatively, due to the differences in business processes of various enterprises, it is difficult to put various business logic suitable for different scenarios into one system and combine them freely according to the scenarios.

In view of the above, in order to break through the limitations of implementation of business logic in a conventional system, a modeling device and a modeling method thereof that may effectively establish business logic capable of completely representing an overall system through unified model description are provided.

### SUMMARY

The disclosure provides a modeling device of a business logic representation model and a modeling method thereof capable of completely representing business logic of an overall system through a unified model and effectively establishing the unified model through the modeling device.

According to an embodiment of the disclosure, a modeling device of a business logic representation model provided by the disclosure includes a memory device and a processing device. The memory device is configured to store a plurality of units. The processing device is coupled to the memory device. The processing device executes the units to establish a plurality of action models and a plurality of data models according to a plurality of action metadata and establish an action logic graph according to the action models and the data models.

According to an embodiment of the disclosure, a modeling method of a business logic representation model provided by the disclosure includes the following steps. A plurality of action models and a plurality of data models are established according to a plurality of action metadata. An action logic graph is established according to the action models and the data models.

To sum up, in the modeling device of the business logic representation model and the modeling method thereof, a combination of a plurality of action models and corresponding data models may be designed to implement various types of business logic models. In the modeling device of the business logic representation model and the modeling method thereof provided by the disclosure, the action logic graph capable of describing the business logic of the overall system may be easily and effectively established.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of a modeling device of a business logic representation model according to an embodiment of the disclosure.

FIG. 2 is a flow chart of a modeling method of the business logic representation model according to an embodiment of the disclosure.

FIG. 3 is a schematic diagram of a business logic model according to an embodiment of the disclosure.

FIG. 4 is a schematic diagram of an action logic graph according to an embodiment of the disclosure.

FIG. 5 is a schematic view of a plurality of units stored by a memory device according to an embodiment of the disclosure.

FIG. 6 is a flow chart of a modeling method of the business logic representation model according to another embodiment of the disclosure.

### DESCRIPTION OF THE EMBODIMENTS

Descriptions of the disclosure are given with reference to the exemplary embodiments illustrated by the accompanying drawings. Wherever possible, the same reference numbers are used in the drawings and the description to refer to the same or like parts.

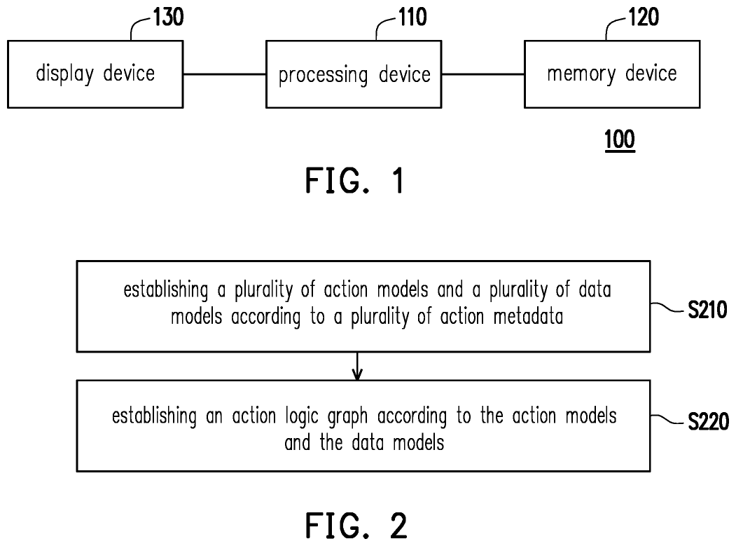

FIG. 1 is a schematic view of a modeling device of a business logic representation model according to an embodiment of the disclosure. Referring to FIG. 1, a modeling device 100 of a business logic representation model may include a processing device 110, a memory device 120, and a display device 130. In this embodiment, the modeling device 100 may be implemented by a computer apparatus exhibiting computation functions such as a personal computer (PC), a tablet, or a server. The processing device 110 may include, for example, a central processing unit (CPU) or a programmable microprocessor for general or special use, a digital signal processor (DSP), an application specific integrated circuit (ASIC), a programmable logic device (PLD), any other similar device, or a combination of the foregoing devices. The processing device 110 may include related circuits configured for implementing various embodiments of the disclosure. Further, the memory device 120 may be a memory, and the memory device 120 may store related programs, modules, or algorithms for implementing various embodiments of the disclosure for the processing device 110 to perform accessing and execution.

In this embodiment, the memory device 120 may store a plurality of units or modules for the processing device 110 to obtain and execute functions/executable programs corresponding to the units or modules through the memory device 120. The units or modules may correspond to, for example, a plurality of programs, modules, or algorithms. In this embodiment, the processing device 110 may generate a business logic representation model through executing the units or the modules, and the business logic representation model may be represented or described through an action logic graph. Further, the modeling device 100 may display the action logic graph through the display device 130. Nevertheless, in some embodiments of the disclosure, the display device 130 in the modeling device 100 is an optional hardware configuration.

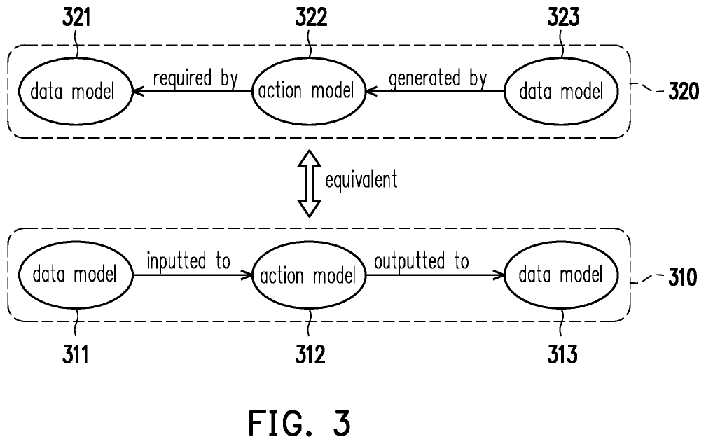

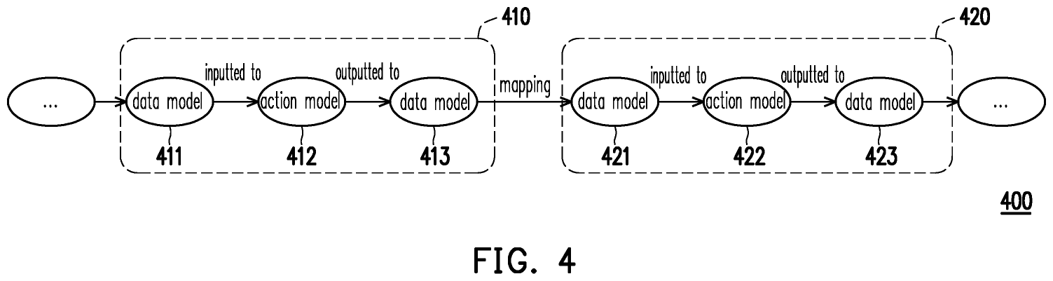

FIG. 2 is a flow chart of a modeling method of the business logic representation model according to an embodiment of the disclosure. Referring to FIG. 1 and FIG. 2, the modeling device 100 of the business logic representation model may execute the flow chart shown in FIG. 2 to generate the business logic representation model. In step S210, the processing device 110 may establish a plurality of action models and a plurality of data models according to a plurality of action metadata. In this embodiment, the plurality of the action metadata may correspond to calling of a plurality of application programming interface (API) service types, and the API services are configured to implement a plurality of business data applications and operations (business logic). The processing device 110 may establish different action models and different data models according to different action metadata. In step S220, the processing device 110 may establish an action logic graph according to the action models and the data models. In this embodiment, the action logic graph is formed by a plurality of business logic models, and each of the business logic models may be formed by one action model and two data models. In this regard, implementation of the business logic models and the action logic graph are described in detail with reference to FIG. 3 and FIG. 4.

Referring to FIG. 3, FIG. 3 is a schematic diagram of a business logic model according to an embodiment of the disclosure. It should be noted that the action logic graph provided by the disclosure is implemented through a graph model, that is, business logic is described through “nodes” and “edges”, and the action logic graph includes two basic node types of action and data. In a business logic model 310 shown in FIG. 3, the business logic model 310 may include an action model 312, a data model 311, and a data model 313. The action model 312 is disposed between the data model 311 and the data model 313. Two basic relationships are expressed between the action model 312 and the data model 311 and between the action model 312 and the data model 313 through directed edges: “data is the input of the action” and “data is the output of the action”. In other words, the data model 311 acts as data input to input the action model 312. The data model 313 acts as data output to be outputted from the action model 312. The action model 312 is defined as a minimum granularity business logic execution unit.

Nevertheless, the business logic model 310 may also be equivalent to representation of a business logic model 320. In the business logic model 320 shown in FIG. 3, the business logic model 320 may include an action model 322, a data model 321, and a data model 323. The action model 322 is disposed between the data model 321 and the data model 323. Two basic relationships are expressed between the action model 322 and the data model 321 and between the action model 322 and the data model 313 through directed edges: “action requires data” (equivalent to “data is the input of action”) and “action generates data” (equivalent to “data is the output of action”). In other words, the data model 321 is the data required by the data model 322, and the data model 323 is the data generated by the data model 322.

Referring to FIG. 4, FIG. 4 is a schematic diagram of an action logic graph according to an embodiment of the disclosure. An action logic graph 400 in FIG. 4 is formed by a plurality of business logic models, and the number of the business logic models is not limited to the model number shown in FIG. 4. FIG. 4 is only used for the following explanation by showing a part of the action logic graph. It should be noted that the processing device 110 may generate a plurality of action model types. In this regard, the action model types may include, for example, various microservice APIs used to represent a microservice architecture. The action model types may include, for example, some simple business logic that does not require writing codes, may define formula logic through a scripting language to make it more flexible, and are also suitable for implementing some business logic that is prone to change. The action model types may include, for example, obtaining variables, so as to improve the reusability and extensibility of the action model by adding variables during execution of the action. The action of obtaining the variable types may be configured to obtain variable value data of a plurality of variables in different scenarios. The action model types may include, for example, data conversion processing such as sorting, grouping, filtering, and column calculating. The data conversion processing logic is defined in a structured configuration mode, and mutual transformation between a plurality of different object hierarchical structure data is achieved. The action model types may include, for example, a service orchestration used to represent the microservice architecture, so as to act as a supplement for calling the microservice types. The service orchestration may solidify and achieve some combinations of business logic. The action model types may include, for example, performing interactive processing. In some implementation scenarios of the disclosure, when some action models in a business system do not have certain automated business logic processing capabilities and need to rely on interactive processing, these action models may be designed to require action input data to form tasks to be processed. In this regard, these action models may automatically send the tasks to designated users in the business system to ask the users to perform interactive processing. Further, these action models may then treat the processed data as action output to be submitted to the business system for continued circulation, and execution of the interactive processing is thus completed. Alternatively, the processing device 110 may automatically expand or manually design a new action model type according to business development.

Business logic models 410 and 420 in an action logic graph 400 are taken as an example, node types of action models 412 and 422 and data models 411, 413, 421, and 423 may be derived from the processing device 110 to express various types of business logic and data types. Nevertheless, the action logic graph generated by the modeling device 100 of the disclosure is not limited to the action logic graph 400 shown in FIG. 4. Based on characteristics of a graph structure, the processing device 110 may connect any number of nodes to better describe the logical corresponding relationship between actions and data. The processing device 110 may further add existing functions of an information system, operations that need to be manually completed, and more business logic types into the action logic graph 400. Moreover, various business logic suitable for different scenarios may be added to the action logic graph 400 for free combinations according to scenarios.

For instance, in the action logic graph 400 shown in FIG. 4, the processing device 110 may derive the action model 412 of a basic calling service type according to, for example, business requirements of a basic calling service, or derive the action model 422 of a formula calculation type according to business requirements of formula calculation. Therefore, the action model 412 may, for example, define an API address, and the action model 422 may, for example, define a corresponding formula expression. Nevertheless, in some embodiments of the disclosure, the action model 412 or the action model 422 may also correspond to interactive processing services or other extensibility. In this embodiment, the data model 411 and the data model 421 may be derived from corresponding data objects or data fields. The data model 413 and the data model 423 are output data describing or defining the action model 412 and the action model 422. Moreover, the data between the business logic models 410 and 420 or between the data model 413 and the data model 421 may have different object hierarchical structures. Therefore, data transformation and transmission may be achieved by establishing mapping between the data model 413 and the data model 421. In this regard, in this embodiment, the processing device 110 may automatically recognize and convert the names, types, or language description, etc. of the data in the data model 413 and the data model 421 through, for example, natural language processing (NLP), and thus may automatically establish the data mapping relationship between different data models of different business logic.

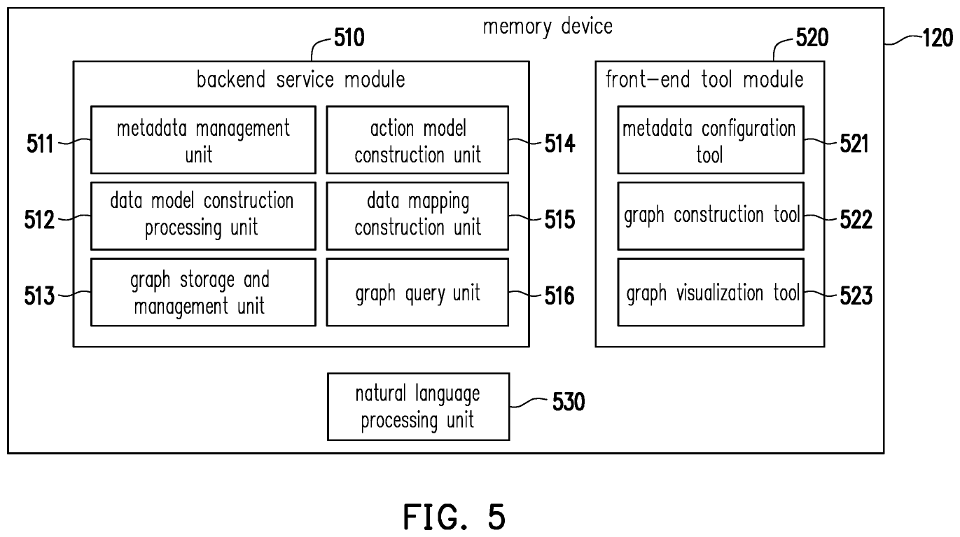

FIG. 5 is a schematic view of a plurality of units stored by a memory device according to an embodiment of the disclosure. Referring to FIG. 5, the memory device 120 may store, for example, a plurality of units and tools as shown in FIG. 5, and the units and tools correspond to a plurality of functional programs or algorithms. The memory device 120 may store a backend service module 510, a front-end tool module 520, and a natural language processing unit 530. The backend service module 510 may include a metadata management unit 511, a data model construction processing unit 512, a graph storage and management unit 513, an action model construction unit 514, a data mapping construction unit 515, and a graph query unit 516. The front-end tool module 520 may include a metadata configuration tool 521, a graph construction tool 522, and a graph visualization tool 523.

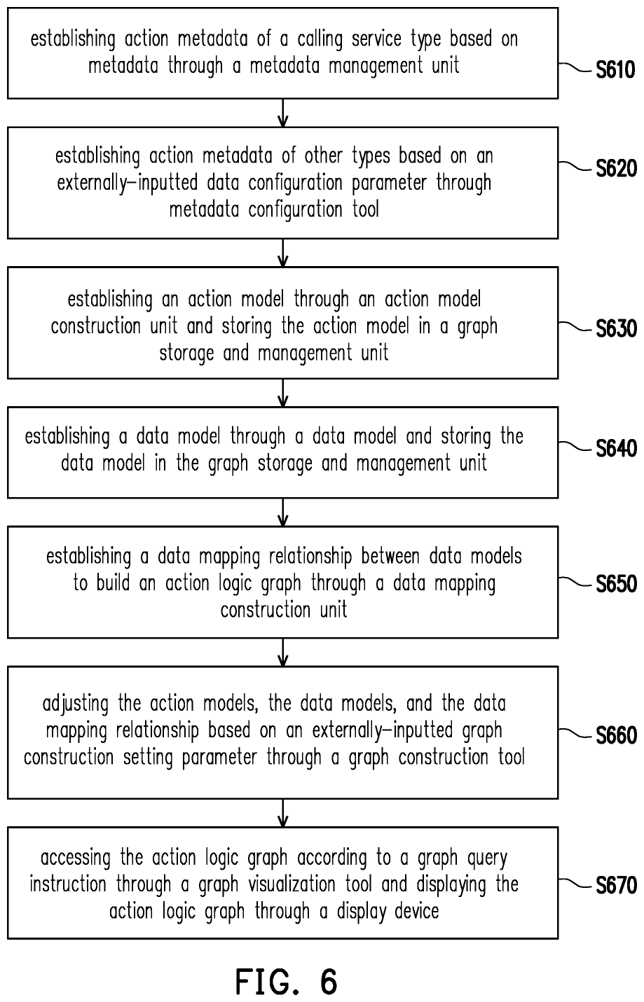

FIG. 6 is a flow chart of a modeling method of the business logic representation model according to another embodiment of the disclosure. Referring to FIG. 1 and FIG. 5 to FIG. 6, the modeling device 100 of the business logic representation model may perform the following steps S610 to S670 to generate the action logic graph. In step 5610, the processing device 110 may execute the metadata management unit 511 to establish action metadata of a calling service type based on metadata. In step S620, the processing device 110 may execute the metadata configuration tool 521 to establish action metadata of other types based on an externally-inputted graph construction configuration. In step S630, the processing device 110 may execute the action model construction unit 514 to establish an action model and store the action model in the graph storage and management unit 513. For instance, regarding the action logic graph 400 of FIG. 4, the processing device 110 may execute the action model construction unit 514 to automatically establish the action models 412 and 422. In step S640, the processing device 110 may execute the data model construction processing unit 512 to establish a data model and store the data model in the graph storage and management unit 513. For instance, regarding the action logic graph 400 of FIG. 4, the processing device 110 may execute the data model construction processing unit 512 to automatically establish the data models 411 and 421. In step S650, the processing device 110 may execute the data mapping construction unit 515 to establish a data mapping relationship between the data models to establish the action logic graph. For instance, regarding the action logic graph 400 of FIG. 4, the processing device 110 may execute the data mapping construction unit 515 to automatically establish the data mapping relationship between the data models 413 and 421. In some embodiments of the disclosure, the processing device 110 may establish the data mapping relationship between the data models 413 and 421 through the data mapping construction unit 515 together with the natural language processing unit 530.

In step S660, the processing device 110 may execute the graph construction tool 522 to adjust the action models, the data models, and the data mapping relationship based on an externally-inputted graph construction setting. In step S670, the processing device 100 may access the action logic graph according to a graph query instruction through the graph visualization tool 523 and display the action logic graph through the display device 130. For instance, regarding the action logic graph 400 of FIG. 4, a user may query the action logic graph 400 by operating an input device (e.g., a keyboard) of the modeling device 110, and the processing device 110 displays the action logic graph 400 on the display device 130 according to a query command. Therefore, in the modeling method and the modeling device 100 of the business logic representation model provided by this embodiment, the action logic graph may be automatically established, and the action logic graph may be viewed and adjusted through the front-end tool module. In addition, in some embodiments of the disclosure, the abovementioned step S620, step S660, and step S670 may be selectively executed steps.

In view of the foregoing, in the disclosure, the modeling device of the business logic representation model and the modeling method thereof rely on natural language processing. In the case that complete metadata is provided, the action logic graph of the application model capable of describing the business logic may be easily and effectively established through a manner which is mostly performed by the modeling device automatically and is minimally combined with manual inspection and adjustment selectively. Further, unlike conventional methods such as domain modeling, business process modeling, business organization modeling, etc. based on business analysis, in the modeling device of the business logic representation model and the modeling method thereof provided by the disclosure, the action logic graph may directly correspond to the implemented business logic and data of an actual system, such as API, parameters, and return value data, so that such model may be interpreted and may be effectively executed. More importantly, in the modeling device of the business logic representation model and the modeling method thereof provided by the disclosure, various business logic suitable for different scenarios may be put into one system and may be freely combined according to the scenarios. In this way, the combination of business logic is flexible, such that the formation of a complex application system through the combination of fine-grained business logic fragments is achieved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A modeling device of a business logic representation model, comprising:
a memory device, configured to store a plurality of units; and
a processing device, coupled to the memory device,
wherein the processing device executes the units to establish a plurality of action models and a plurality of data models according to a plurality of action metadata and establish an action logic graph according to the action models and the data models.

2. The modeling device according to claim 1, wherein the action logic graph is formed by a plurality of business logic models, wherein each of the business logic models is formed by an action model, a first data model, and a second data model,
wherein the action model is disposed between the first data model and the second data model, the first data model acts as data input to input the action model, and the second data model acts as data output to be outputted from the action model.

3. The modeling device according to claim 2, wherein the action metadata respectively corresponds to calling of a plurality of service types.

4. The modeling device according to claim 1, wherein the action metadata is generated by the processing device according to an externally-inputted data configuration parameter.

5. The modeling device according to claim 1, wherein the action models correspond to a plurality of business logic executions.

6. The modeling device according to claim 5, wherein the data models comprise data required by the action models to perform business logic executions and generated data.

7. The modeling device according to claim 1, wherein the processing device establishes a data mapping relationship between different data models of different business logics to establish the action logic graph.

8. The modeling device according to claim 7, wherein the processing device establishes the data mapping relationship between different data models of different business logics through natural language processing.

9. The modeling device according to claim 7, wherein the processing device adjusts the action models, the data models, and the data mapping relationship according to an externally inputted graph construction setting.

10. The modeling device according to claim 7, wherein the processing device accesses the action logic graph according to a graph query instruction and displays the action logic graph through a display device.

11. A modeling method of a business logic representation model, comprising:
establishing a plurality of action models and a plurality of data models according to a plurality of action metadata; and
establishing an action logic graph according to the action models and the data models.

12. The modeling method according to claim 11, wherein the action logic graph is formed by a plurality of business logic models, wherein each of the business logic models is formed by an action model, a first data model, and a second data model,
wherein the action model is disposed between the first data model and the second data model, the first data model acts as data input to input the action model, and the second data model acts as data output to be outputted from the action model.

13. The modeling method according to claim 12, wherein the action metadata respectively corresponds to calling of a plurality of service types.

14. The modeling method according to claim 11, wherein the action metadata is generated by the processing device according to an externally-inputted data configuration parameter.

15. The modeling method according to claim 11, wherein the action models correspond to a plurality of business logic executions.

16. The modeling method according to claim 15, wherein the data models comprise data required by the action models to perform business logic executions and generated data.

17. The modeling method according to claim 11, wherein the step of establishing the action logic graph comprises:
establishing a data mapping relationship between different data models of different business logics to establish the action logic graph.

18. The modeling method according to claim 17, wherein the step of establishing the action logic graph further comprises:
establishing the data mapping relationship between different data models of different business logics through natural language processing.

19. The modeling method according to claim 17, further comprising:
adjusting the action models, the data models, and the data mapping relationship according to an externally inputted graph construction setting.

20. The modeling method according to claim 17, further comprising:
accessing the action logic graph according to a graph query instruction, and displaying the action logic graph through a display device.
